(19) United States
(12) Patent Application Publication
(10) Pub. No.: US 2008/0213965 A1
(43) Pub. Date: Sep. 4, 2008

(54) METHOD FOR MANUFACTURING DMOS DEVICE

(76) Inventor: Chul Jin YOON, Suwon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/965,086

(22) Filed: Dec. 27, 2007

(30) Foreign Application Priority Data
Dec. 27, 2006 (KR) 10-2006-0134641

(51) Int. Cl. H01L 21/336

(52) U.S. Cl. 438/305; 257/E21.417

(57) ABSTRACT

A method for manufacturing a semiconductor device is provided. The semiconductor device may be a drain extended metal-oxide-semiconductor (DMOS) device. The method includes: forming a gate insulating film on a semiconductor substrate having an active region; forming a gate on the gate insulating film; forming a low-concentration source region and a low-concentration drain region over the semiconductor substrate by implanting low-concentration impurity ions using the gate as a mask; forming a spacer on sides of the gate; forming a silicide area block (SAB) pattern over the semiconductor substrate, covering a portion of the gate and the low-concentration drain region; and forming a high-concentration source region and a high-concentration drain region over the semiconductor substrate by implanting high-concentration impurity ions using the SAB pattern as a mask.

### CROSS-REFERENCE TO RELATED APPLICATIONS

The present application claims the benefit of priority under 35 U.S.C. 119 to Korean Patent Application No. 10-2006-0134641, filed on Dec. 27, 2006, the entire contents of which are incorporated herewith by reference.

### BACKGROUND

The present invention relates to a method for manufacturing a drain extended metal-oxide-semiconductor (DMOS) device.

A DMOS device may have an increased breakdown voltage by extending the channel length of the DMOS device as a result of an extended drain region. The DMOS device is often used in a power supply apparatus. The DMOS device may comprise a semiconductor substrate, an N well or a P well, a low-concentration source/drain region, a high-concentration source/drain region, a gate, a sacrifice oxide film, a spacer, an interlayer dielectric layer, and a contact hole. In manufacturing the DMOS device, a photoresist pattern is used for forming the high-concentration source/drain aligned with the gate. Further, a process is performed for forming a silicide area block (SAB) oxide film pattern aligned with the gate. Also, the overlay management requires a fine photo process, and a pattern forming process is required to be perform for at least two times.

### SUMMARY

Embodiments consistent with the present invention provide a method for manufacturing a semiconductor device, such as a DMOS device.

In one embodiment, the semiconductor device includes a substrate, on which a well structure, a source region, a drain region, a gate insulating layer, and a gate are formed. The method includes providing the substrate and performing an ion implantation process on the source region and the drain region of the substrate using a silicide area block (SAB) pattern as a mask.

A method for manufacturing a DMOS device according to the embodiment includes: forming a gate insulating film on a semiconductor substrate having an active region; forming a gate on the gate insulating film; forming a low-concentration source region and a low-concentration drain region over the semiconductor substrate by implanting low-concentration impurity ions using the gate as a mask; forming a spacer on sides of the gate; forming a silicide area block (SAB) pattern over the semiconductor substrate, covering a portion of the gate and the low-concentration drain region; and forming a high-concentration source region and a high-concentration drain region over the semiconductor substrate by implanting high-concentration impurity ions using the SAB pattern as a mask.

Detailed description of one or more embodiments consistent with the present invention will be discussed below with reference to the accompanying drawings. Other features will be apparent to those skilled in the art from the detailed description and the drawings, as well as from the appended claims.

### BRIEF DESCRIPTION OF THE DRAWINGS

FIGS. 1 to 7 are sectional views showing a method for manufacturing a DMOS device according to an embodiment consistent with the present invention.

### DETAILED DESCRIPTION

Hereinafter, embodiments consistent with the present invention will be described in detail with reference to the accompanying drawings. Same constituents or components are represented by same reference numerals, whenever possible.

Further, when a layer (film), area, pattern, or structure is described as being formed on, above, over, below, under, or beneath another layer (film), area, pattern, or structure, it is understood that either the layer (film), area, pattern, or structure is formed either in direct contact with the other layer (film), area, pattern, or structure, or in indirect contact with the other layer, area, pattern, or structure with additional layers (films), areas, patterns, or structures formed in between.

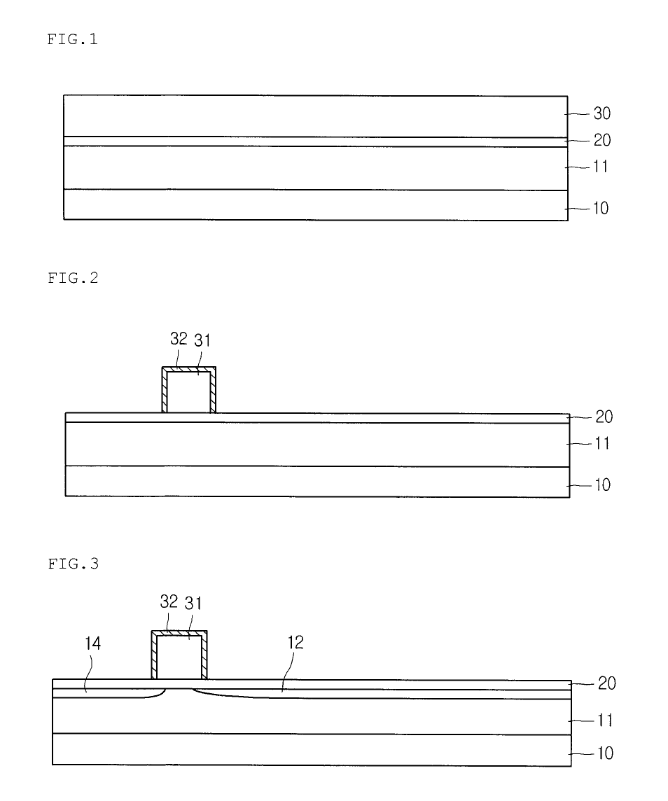

FIGS. 1-7 illustrates sectional views corresponding to methods for manufacturing a DMOS device. The DMOS device may include a drain extended P-MOS device, as well as a drain extended N-MOS device.

Referring to FIG. 1, a semiconductor substrate 10 is provided having a device isolating region (not shown) and an active region (not shown) formed thereon. A well structure 11, such as a P-well or an N-well, is formed on semiconductor substrate 10 by implanting impurity ions in semiconductor substrate 10. In one embodiment, semiconductor substrate 10 may be a silicon substrate implanted with P type or N type impurity ions. Further, a gate insulating film 20 and a gate conducting layer 30 are sequentially deposited on semiconductor substrate 10 having the active region.

Referring to FIG. 2, a photoresist film (not shown) is formed on gate conducting layer 30. The photoresist film may be exposed and developed to form a photoresist pattern (not shown). Gate conducting layer 30 may be etched by using the photoresist pattern as an etching mask, thereby forming a gate 31. Further, the surface of gate 31 is oxidized to form a sacrifice oxide film 32.

Referring to FIG. 3, low-concentration impurity ions are implanted in well structure 11 using gate 31 as a mask, thereby forming a low-concentration drain region 12 and a low-concentration source region 14. In one embodiment, low-concentration drain region 12 may be formed to have a length longer than that of low-concentration source region 14.

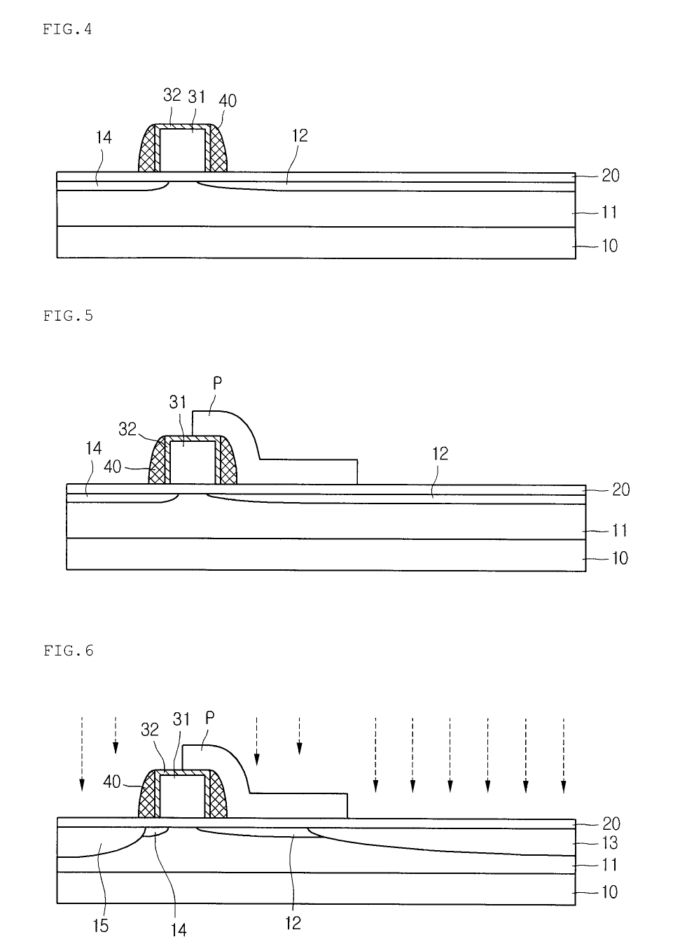

Referring to FIG. 4, after a spacer insulating layer (not shown) is deposited on the resultant structure, an etchback process may be performed to form a spacer 40 on sides of gate 31. In one embodiment, the spacer insulating layer may comprise, for example, a nitride film made of a nitride material.

Referring to FIG. 5, a silicide area block (SAB) oxide film (not shown) may be formed on the resultant structure. Further, a photoresist film (not shown) may be coated on the SAB oxide film. The photoresist film may be exposed and developed to form a photoresist pattern (not shown) covering a portion of the upper surface of gate 31 close to low-concentration drain region 12 and a portion of low-concentration drain region 12. Further, an etching process may be performed using the photoresist pattern (not shown) as an etching mask to form an SAB oxide film pattern P. SAB oxide film pattern P covers a portion of the upper surface of gate 31 close to low-concentration drain region 12 and a portion of low-concentration drain region 12. In one embodiment, if the length of SAB oxide film pattern P is too small, the breakdown voltage of the DMOS device may not be increased due to the small length of low-concentration drain region 12. On the other hand, if SAB oxide film pattern P is too long, the breakdown voltage may be increased, however, the integration of the semiconductor device may be deteriorated. Therefore, the length of SAB oxide film pattern P should be suitably controlled.

Referring to FIG. 6, high-concentration impurity ions are implanted using SAB oxide film pattern P as a mask to form a high-concentration source region 15, and a high-concentration drain region 13 in well structure 11.

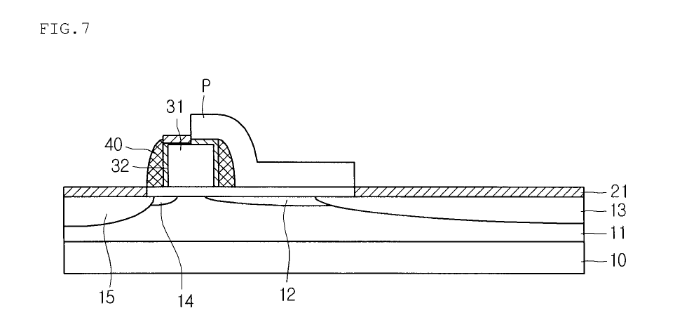

Referring to FIG. 7, after high-concentration source region 15 and drain region 13 are formed, a silicide process may be performed on the resultant structure having the SAB oxide film pattern P, so as to form a silicide layer 21 on high-concentration source region 15, on a portion of the upper surface of gate 31, and on high-concentration drain region 13. Further, an interlayer dielectric layer (not shown) may be deposited on the resultant structure. Further, a contact hole (not shown) may be formed on the interlayer dielectric layer and a general subsequent process may be performed, thereby manufacturing the DMOS device.

As discussed above, in one embodiment consistent with the present invention, a mask pattern and a silicide area block (SAB) oxide film pattern on a high-concentration source/drain region may be formed in a single photo process, making it possible to reduce the time and costs of manufacturing the DMOS device.

Any reference in this specification to “one embodiment,” “an embodiment,” “example embodiment,” etc., means that particular features described in connection with the “embodiment” is included in at least one embodiment consistent with the present invention. The appearances of such phrases in various places in the specification are not necessarily all referring to the same embodiment. Further, when a particular feature is described in connection with any embodiment, it is submitted that it is within the purview of one skilled in the art to effect such feature in connection with other possible embodiments.

Although embodiments consistent with the present invention have been described with reference to a number of illustrative embodiments thereof, it is to be understood that numerous other modifications and/or embodiments can be devised by those skilled in the art that will fall within the spirit and scope of the appended claims. Moreover, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A method for manufacturing a semiconductor device, comprising:
forming a gate insulating film on a semiconductor substrate having an active region;
forming a gate on the gate insulating film;
forming a low-concentration source region and a low-concentration drain region over the semiconductor substrate by implanting low-concentration impurity ions using the gate as a mask;
forming a spacer on sides of the gate;
forming a silicide area block (SAB) pattern over the semiconductor substrate, covering a portion of the gate and the low-concentration drain region; and
forming a high-concentration source region and a high-concentration drain region over the semiconductor substrate by implanting high-concentration impurity ions using the SAB pattern as a mask.

2. The method according to claim 1, wherein the spacer comprises a nitride film.

3. The method according to claim 1, wherein the SAB pattern covers a portion of the upper surface of the gate close to the low-concentration drain region.

4. The method according to claim 1, wherein the SAB pattern covers a portion of the low-concentration drain region.

5. The method according to claim 1, wherein the SAB pattern covers a portion of the upper surface of the gate close to the low-concentration drain region and a portion of the low-concentration drain region.

6. The method according to claim 1, further comprising:
after forming the high-concentration source region and the high-concentration drain region, performing a silicide process on the resultant structure to form a silicide layer on the high-concentration source region, on a portion of the upper surface of the gate, and on the high-concentration drain region.

7. A method for manufacturing a semiconductor device having a substrate, on which a well structure, a source region, a drain region, a gate insulating layer, and a gate are formed, the method comprising providing the substrate and performing an ion implantation process on the source region and the drain region of the substrate using a silicide area block (SAB) pattern as a mask.

8. The method according to claim 7, wherein performing the ion implantation process comprises forming a high-concentration source region and a high-concentration drain region using the SAB pattern as a mask.

9. The method according to claim 8, wherein forming the high-concentration source region and the high-concentration drain region comprises implanting high-concentration impurity ions using the SAB pattern covering a portion of a low-concentration source and a low-concentration drain region as a mask.

10. The method according to claim 7, wherein the SAB pattern covers a portion of the upper surface of the gate close to the drain region and a portion of the low-concentration drain region.

11. The method according to claim 7, further comprising forming a silicide layer on the source region, on a portion of an upper surface of the gate, and on the drain region using the SAB pattern as a mask.

12. The method according to claim 7, wherein the semiconductor device comprises a DMOS device having a drain extended P-type MOS structure.

13. The method according to claim 7, wherein the semiconductor device comprises a DMOS device having a drain extended P-type MOS structure.
